(19) United States
(12) Patent Application Publication
(10) Pub. No.: US 2009/0102529 A1
(43) Pub. Date: Apr. 23, 2009

(54) SHIFTING INACTIVE CLOCK EDGE FOR NOISE REDUCTION

(75) Inventors: Igor Arsovski, Williston, VT (US); Joseph A. Iadanza, Hinesburg, VT (US); Jason M. Norman, Essex Junction, VT (US); Hemen Shah, South Burlington, VT (US); Sebastian T. Ventrone, South Burlington, VT (US)

Correspondence Address: HOFFMAN WARNICK LLC, 75 STATE ST, 14TH FLOOR, ALBANY, NY, 12207, US

(73) Assignee: International Business Machines Corporation, Armonk, NY (US)

(21) Appl. No.: 11/876,871

(22) Filed: Oct. 23, 2007

(51) Int. Cl. H03K 3/017

(52) U.S. Cl. 327/175; 327/295

(57) ABSTRACT

An integrated circuit and a design structure are disclosed. An integrated circuit may comprise: multiple clocked elements; a clock signal source providing clock signals to the multiple clocked elements; and a clock shifting means coupled between the clock signal source and each of the multiple clocked elements; wherein the clock shifting means shifts clock signals of the multiple clocked elements such that the clock signals of the multiple clocked elements have aligned active edges and misaligned inactive edges to reduce the clock noise generated by the inactive edges of the clock signals.

The current application is related to co-pending U.S. patent application Ser. No. 11/457,916, currently pending.

### FIELD OF THE DISCLOSURE

The disclosure relates generally to an integrated circuit, and more particularly, to a method and system for shifting inactive clock signal edges for reducing noise level.

### BACKGROUND ART

In a typical integrated circuit (IC), clock nets are heavily loaded, and typically need to have very tight tolerance, which results in large drive strengths of the buffers in, e.g., the clock tree. An IC design may use both edges (leading edge and falling edge) of a single clock. For example, a double data rate (DDR) interface uses both edges of a clock to achieve the desired functionality. However, for general data transfer using generic logic resources, an IC uses only one edge of a single clock, usually the leading edge. For example, current state of the art clock generators and methods of distributing a clock tree typically have four edges for a two-phase clock cycle, i.e., a launch edge, a capture edge, and two opposite transition edges of the two phase clock. The critical edges are the launch edge and the capture edge, which are used to maintain the functionality of the clock signal, e.g., a proper timing. However, the inactive edges, e.g., the two opposite transition edges are not used for functional purpose, they contribute in creating power supply noise. As shown in FIG. 1, each inactive clock edge 110 may creates noise spike 112 as active edges 114 do. Given that inactive edges are not critical to the functionality of a clock signal, the parasitic noise caused by the inactive edges is less tolerable.

As such, there is a need in the art to manipulate inactive clock edges to reduce clock noise within the silicon of an IC. The present state of the art technology does not provide a satisfactory solution to this need.

### SUMMARY OF THE DISCLOSURE

An integrated circuit and a design structure are disclosed. An integrated circuit may comprise: multiple clocked elements; a clock signal source providing clock signals to the multiple clocked elements; and a clock shifting means coupled between the clock signal source and each of the multiple clocked elements; wherein the clock shifting means shifts clock signals of the multiple clocked elements such that the clock signals of the multiple clocked elements have aligned active edges and misaligned inactive edges to reduce the clock noise generated by the inactive edges of the clock signals.

A first aspect of the disclosure provides a design structure embodied in a machine readable medium used in a design flow process, the design structure comprising a circuit, the circuit comprising: multiple clocked elements; a clock signal source providing clock signals to the multiple clocked elements; and a clock shifting means coupled between the clock signal source and each of the multiple clocked elements; wherein the clock shifting means shifts clock signals of the multiple clocked elements such that the clock signals of the multiple clocked elements have aligned active edges and misaligned inactive edges to reduce the clock noise generated by the inactive edges of the clock signals.

A second aspect of the disclosure provides an integrated circuit comprising: multiple clocked elements; a clock signal source providing clock signals to the multiple clocked elements; and a clock shifting means coupled between the clock signal source and each of the multiple clocked elements; wherein the clock shifting means shifts clock signals of the multiple clocked elements such that the clock signals of the multiple clocked elements have aligned active edges and misaligned inactive edges to reduce the clock noise generated by the inactive edges of the clock signals.

The illustrative aspects of the present disclosure are designed to solve the problems herein described and other problems not discussed, which are discoverable by a skilled artisan.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a clock signal and noise spikes generated by the clock signal according to known art.

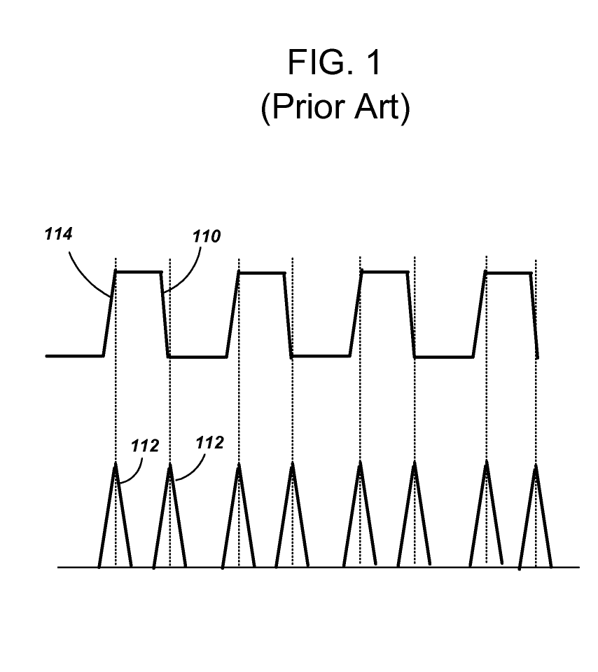

FIG. 2 shows the effect of misaligned inactive clock edges of clock signals on the peak current generated by the inactive clock edges according to one embodiment of the disclosure.

FIG. 3 shows a schematic diagram of a clock path circuit according to one embodiment of the disclosure.

FIG. 4 depicts a block diagram of a general-purpose computer system.

FIG. 5 depicts a block diagram of an exemplary design flow.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

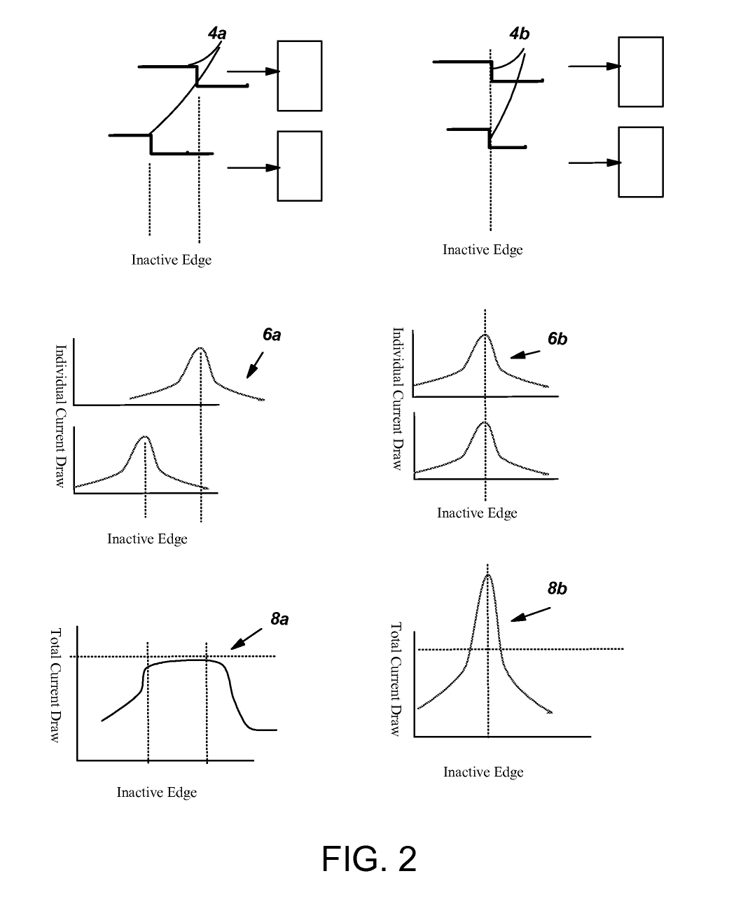

The current disclosure is based on an understanding that if two noise spikes are closer in time, the peak current will be higher in magnitude. On the other hand, if two noise spikes are separated relatively far away in time, the peak current will be lower in magnitude. As such, if clock signals of clocked elements, e.g., latches, SRAMs, flipflops, register files, or other data storage elements, have misaligned/non-coincident inactive edges in time, the peak current generated by the inactive edges will be reduced. As shown in FIG. 2, clocks 4a with misaligned inactive edges generate individual currents 6a with misaligned individual peaks, which results in reduced total peak current 8a, compared with that of total current 8b generated by clocks 4b with aligned inactive edges. In FIG. 2 and the following description, the falling edge of a single clock is used as an illustrative example of an inactive edge, which represents the ordinary clock signal design. However, using the leading edge as an inactive edge is also possible and is included in the scope of the current disclosure.

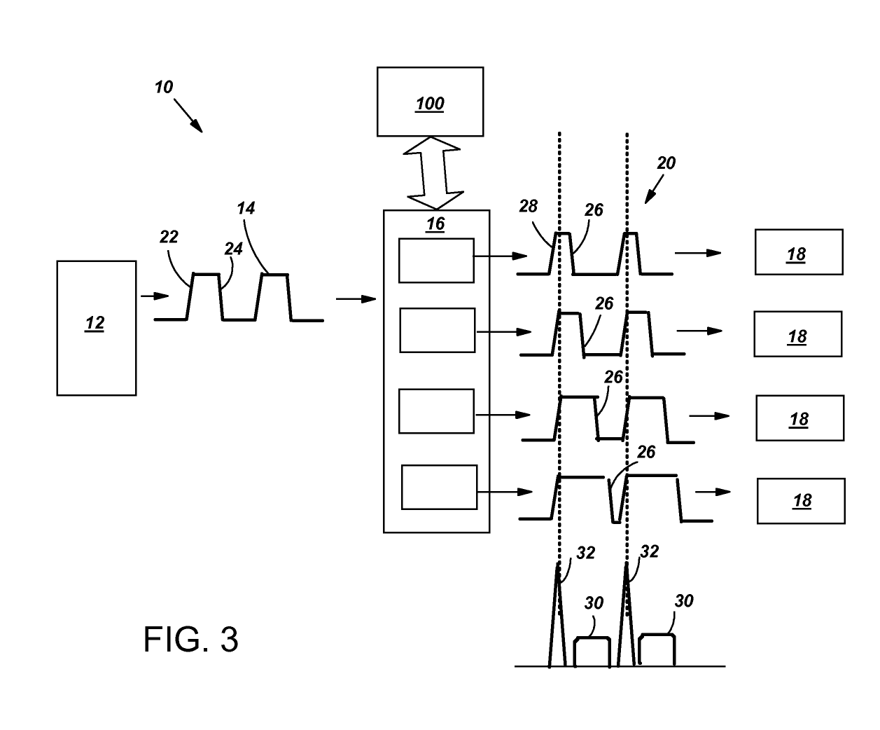

FIG. 3 shows a schematic diagram of a clock path circuit 10 according to one embodiment of the disclosure. As shown in FIG. 3, a clock generator 12 generates a global clock (CLK_G) 14. CLK_G 14 is propagated to a local clock chopper (LCC) 16 before a local clocked element 18. Local clock chopper 16 processes/splits global clock 14 and generates a local clock 20 for each local clocked element 18. As is appreciated, clock structure of an IC may be much more complicated than the example of FIG. 3. However, the disclosure can be applied to all kinds of clock structures. As such, it should be appreciated that a local clocked element 18 may include/represent any clocked elements or groups of clocked elements in an IC, and a local clock 20 may represent any clock signal (i.e., leaf in a clock tree) or a branch of clock signal (i.e., a branch of a clock tree or a clock tree) in a treed clock propagation structure.

In operation, local clock chopper 16 maintains active edges 22 of global clock 14 in the splitting, but shifts inactive edge 24 of global clock 14 to generate local clocks 20. As shown in the illustrative example of FIG. 3, local clocks 20 have inactive edges 26 misaligned to one another. At the same time, local clocks 20 have aligned active edges 28. As such, proper timing of local clocked elements 18 is maintained, while peak current 30 (noise) generated by the inactive edges 26 is reduced compared with peak current 32 generated by active edges 28. According to one embodiment, local clock chopper 16 shifts/distributes inactive edge 26 of local clock signal 20 for each local clocked element 18 in across a period of local clock signal 20. It should be appreciated that any now known or later developed methods or mechanisms may be used to effect the shifting of inactive edges 26, and all are included in the scope of the disclosure. It should also be appreciated that it is not necessary that all local clocks 20 have misaligned inactive edges 26. A group of local clocks 20 may have substantially aligned inactive edges 26.

According to one embodiment, local clock chopper 16 may be controlled by a control system 100, e.g., a computer system. For example, control system 100 may select local clock signals 20 for inactive edge shifting and may determine how an inactive edge 22 of a local clock signal 20 should be shifted. In other words, control system 100 determines and assigns a clock duty cycle for each local clock 20. It is appreciated that in assigning a clock duty cycle, active edge 28 is not varied such that proper timing of the IC is maintained. Any methods or standards/tests may be used in the assignment of clock duty cycle, and all are included in the current disclosure. Basically, to reduce noise, inactive edges of local clocks 20 need to be as misaligned as possible, provided that other design rule constraints are met.

In addition, in the case that a large number of local clocks 20 are involved, weightings may be applied to local clocks 20 in the clock duty cycle assignment. It is appreciated that it is the switching of inactive edges 26 of local clocks 20, not the activities of local clocked elements 18, that generates noise currents at inactive edges. For example, a local clock 20 (e.g., a branch or clock signal leaf) that has the potential to generate more noise may be assigned a priority in the assignment of clock duty cycle. Specifically, clock signals which drive larger numbers of clocked elements need to be assigned higher priority in order to maximize spreading of inactive edges and minimize peak noise. In addition, a local clock signal with a capacitive load higher than a pre-set threshold is may also be assigned a priority. In general clock signals may be evaluated for their potential to create noise due to inactive edge switching and regardless of the cause of the noise generation potential, those clock signals with the highest potential for noise generation or those which potentially generate noise above a pre-set threshold for acceptable noise generation may be prioritized above other clock signals in the IC for clock duty cycle spreading.

In addition, the assignment of a clock duty cycle may involve the consideration of the noise sensitive bandwidth of a nearby circuit such that an inactive edge 26 of a local clock signal 20 falls outside of the noise sensitive bandwidth. For example, if a nearby circuit is sensitive to noise at the middle of a clock cycle, the local clock signal 20 of a clocked element 18 needs to have a clock duty cycle skewed away from 50/50, i.e., inactive clock edge in the middle of a clock cycle.

Moreover, as a functionality requirement, the assigned clock duty cycle needs to leave enough time for a local clocked element 18 to complete data processing. In other words, the shifted clock duty cycle must maintain the minimum pulse-width requirement of the respective clocked element 18. For example, if a local clocked element 18 needs a 20/80 clock duty cycle to complete a data transition, the respective local clock 20 cannot be assigned a clock duty cycle of 10/90.

In addition, it needs to be determined whether the assignment of clock duty cycles maintains proper functionality of the designed IC. For example, it needs to be determined whether, after the shifting of inactive clock edges, the clocked elements are able to be placed and routed according to design rule constraints. Other timing constraints, such as the above-mentioned clock pulse-width, also need to be checked and maintained.

A complete integrated circuit including clock path circuit 10, which may be referred to herein as a design structure, is created in a graphical computer programming language, and coded as a set of instructions on machine readable removable or hard media (e.g., residing on a graphical design system (GDS) storage medium). That is, design structure(s) is embodied in a machine readable medium used in a design process. (The design structure(s) may interface with any part of a machine readable media). The design structure(s) may include a netlist, which describes clock path circuit 10, and may include test data files, characterization data, verification data, or design specifications. If the designer does not fabricate chips or the photolithographic masks used to fabricate chips, the designer transmits the resulting design structure by physical means (e.g., by providing a copy of the storage medium storing the design) or electronically (e.g., through the Internet) to such entities as a foundry, directly or indirectly. The stored design is then converted into the appropriate format (e.g., graphic design system 11 (GDSII)) for the fabrication of photolithographic masks, which typically include multiple copies of the chip design in question that are to be formed on a wafer. The photolithographic masks are utilized to define areas of the wafer (and/or the layers thereon) to be etched or otherwise processed.

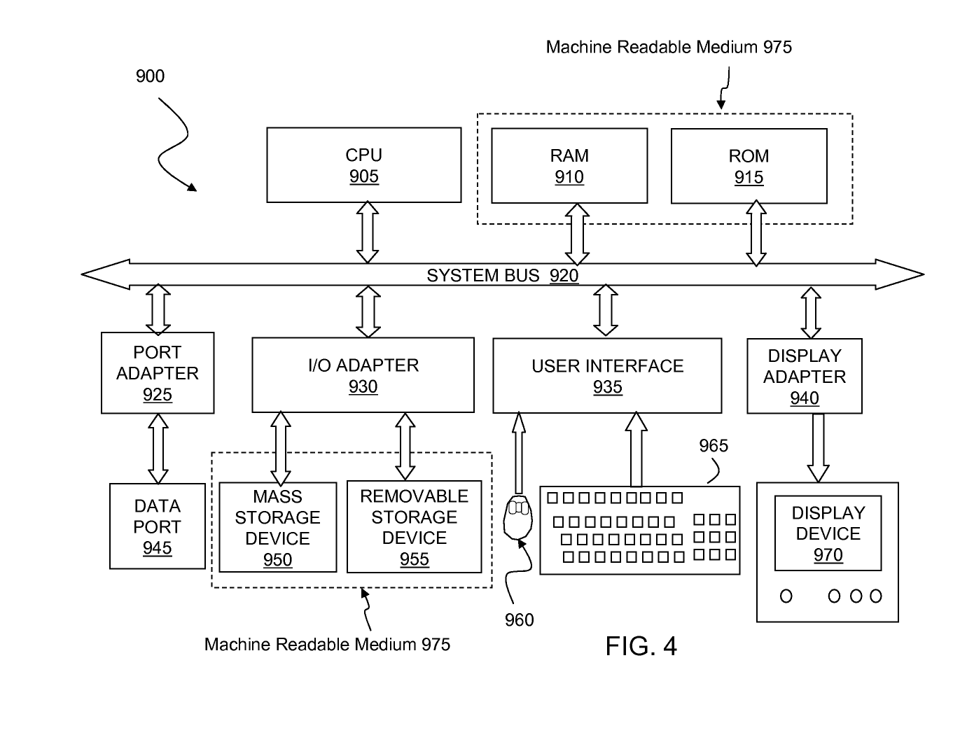

FIG. 4 depicts a block diagram of a general-purpose computer system 900 that can be used to implement clock path circuit 10, and a circuit design structure described herein. The design structure may be coded as a set of instructions on removable or hard media for use by the general-purpose computer 900. The computer system 900 has at least one microprocessor or central processing unit (CPU) 905. The CPU 905 is interconnected via a system bus 920 to machine readable media 975, which includes, for example, a random access memory (RAM) 910, a read-only memory (ROM) 915, a removable and/or program storage device 955, and a mass data and/or program storage device 950. An input/output (I/O) adapter 930 connects mass storage device 950 and removable storage device 955 to system bus 920. A user interface 935 connects a keyboard 965 and a mouse 960 to the system bus 920, a port adapter 925 connects a data port 945 to the system bus 920, and a display adapter 940 connects a display device 970 to the system bus 920. The ROM 915 contains the basic operating system for computer system 900. Examples of removable data and/or program storage device 955 include magnetic media such as floppy drives, tape drives, portable flash drives, zip drives, and optical media such as CD ROM or DVD drives. Examples of mass data and/or program storage device 950 include hard disk drives and non-volatile memory such as flash memory. In addition to the keyboard 965 and mouse 960, other user input devices such as trackballs, writing tablets, pressure pads, microphones, light pens and position-sensing screen displays may be connected to user interface 935. Examples of the display device 970 include cathode-ray tubes (CRT) and liquid crystal displays (LCD).

A machine readable computer program may be created by one of skill in the art and stored in computer system 900 or a data and/or any one or more of machine readable medium 975 to simplify the practicing of this disclosure. In operation, information for the computer program created to run the present disclosure is loaded on the appropriate removable data and/or program storage device 955, fed through data port 945, or entered using keyboard 965. A user controls the program by manipulating functions performed by the computer program and providing other data inputs via any of the above mentioned data input means. The display device 970 provides a way for the user to accurately control the computer program and perform the desired tasks described herein.

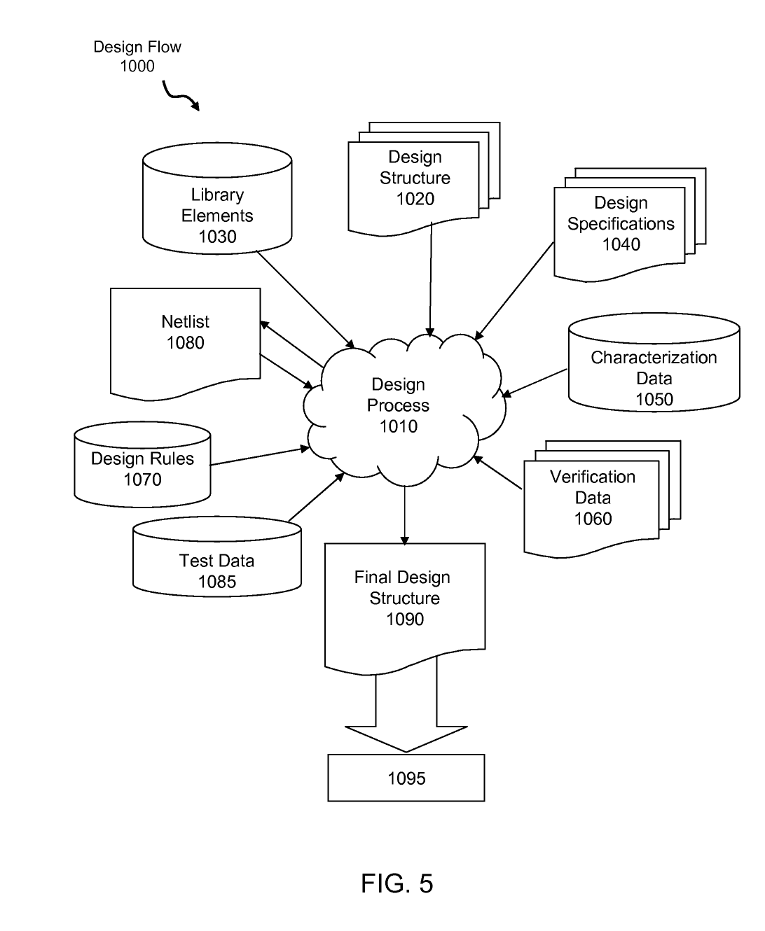

FIG. 5 depicts a block diagram of an example design flow 1000, which may vary depending on the type of IC being designed. For example, a design flow 1000 for building an application specific IC (ASIC) will differ from a design flow 1000 for designing a standard component. A design structure 1020 is an input to a design process 1010 and may come from an IP provider, a core developer, or other design company. The design structure 1020 comprises a clock path circuit 10 in the form of schematics or HDL, a hardware-description language, (e.g., Verilog, VHDL, C, etc.). The design structure 1020 may be on one or more of machine readable medium 975 as shown in FIG. 4. For example, the design structure 1020 may be a text file or a graphical representation of clock path circuit 10. The design process 1010 synthesizes (or translates) clock path circuit 10 into a netlist 1080, where the netlist 1080 is, for example, a list of fat wires, transistors, logic gates, control circuits, I/O, models, etc., and describes the connections to other elements and circuits in an integrated circuit design and recorded on at least one machine readable medium 975.

The design process 1010 includes using a variety of inputs; for example, inputs from library elements 1030 which may house a set of commonly used elements, circuits, and devices, including models, layouts, and symbolic representations, for a given manufacturing technology (e.g., different technology nodes, 32 nm, 45 nm, 90 nm, etc.), design specifications 1040, characterization data 1050, verification data 1060, design rules 1070, and test data files 1085, which may include test patterns and other testing information. The design process 1010 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 1010 without deviating from the scope and spirit of the disclosure.

Ultimately, the design process 1010 translates clock path circuit 10 along with the rest of the integrated circuit design (if applicable), into a final design structure 1090 (e.g., information stored in a GDS storage medium). The final design structure 1090 may comprise information such as, for example, test data files, design content files, manufacturing data, layout parameters, wires, levels of metal, vias, shapes, test data, data for routing through the manufacturing line, and any other data required by a semiconductor manufacturer to produce clock path circuit 10. The final design structure 1090 may then proceed to a stage 1095 of design flow 1000; where stage 1095 is, for example, where final design structure 1090: proceeds to tape-out, is released to manufacturing, is sent to another design house or is sent back to the customer.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A design structure embodied in a machine readable medium used in a design flow process, the design structure comprising a circuit, the circuit comprising:
multiple clocked elements;
a clock signal source providing clock signals to the multiple clocked elements; and
a clock shifting means coupled between the clock signal source and each of the multiple clocked elements;
wherein the clock shifting means shifts clock signals of the multiple clocked elements such that the clock signals of the multiple clocked elements have aligned active edges and misaligned inactive edges to reduce the clock noise generated by the inactive edges of the clock signals.

2. The design structure of claim 1, wherein the clock shifting means further assigns a clock duty cycle to a clock signal of a clocked element such that there is enough time for the clocked element to complete a data processing function.

3. The design structure of claim 1, wherein the clock shifting means further assigns a clock duty cycle to a clock signal of a clocked element such that an inactive edge of the clock signal falls outside of a bandwidth within which a nearby circuit is sensitive to noise.

4. The design structure of claim 1, wherein the clock shifting means further assigns a clock duty cycle to a clock signal of a clocked element based on a potential amount of noise produced by inactive edges of the clock signal.

5. An integrated circuit comprising:
multiple clocked elements;
a clock signal source providing clock signals to the multiple clocked elements; and
a clock shifting means coupled between the clock signal source and each of the multiple clocked elements;
wherein the clock shifting means shifts clock signals of the multiple clocked elements such that the clock signals of the multiple clocked elements have aligned active edges and misaligned inactive edges to reduce the clock noise generated by the inactive edges of the clock signals.
